(19) United States
(12) Patent Application Publication
(10) Pub. No.: US 2024/0410954 A1
(43) Pub. Date: Dec. 12, 2024

(54) Method, apparatus, storage medium and terminal device for estimating battery capacity

(71) Applicant: Yiu Wa LEUNG, N.T., Hong Kong (HK)

(72) Inventors: Yiu Wa LEUNG, N.T., Hong Kong (HK); Kai Ming WONG, N.T., Hong Kong (HK); Kwun Yu LAM, N.T., Hong Kong (HK)

(21) Appl. No.: 18/810,807

(22) Filed: Aug. 21, 2024

Related U.S. Application Data
(63) Continuation of application No. 17/197,220, filed on Mar. 10, 2021.

(51) Int. Cl. G01R 31/388; H02J 7/00

(52) U.S. Cl. CPC G01R 31/388; H02J 7/0047

(57) ABSTRACT

A method for estimating a battery capacity includes: determining the measurement voltage of the battery before charging or discharging, the electric charge change of the battery during charging or discharging and the measurement voltage the battery after charging or discharging; Obtaining the correlation data between the voltage and the electric charge of the battery; Updating the correlation data according to the measurement voltage of the battery before charging or discharging, the measurement voltage of the battery after charging or discharging, the electric charge change, and the correlation data; and determining the battery capacity according to the updated correlation data. The invention can update the correlation data between the voltage and charge of the battery and in turn determine the battery capacity, so that the battery capacity can be determined precisely in the course of its life cycle even as the battery ages.

### CROSS REFERENCE TO RELATED APPLICATIONS

This application is a continuation of the U.S. application Ser. No. 17/197,220 filed on 10 Mar. 2021, entitled “Method, Apparatus, Storage Medium and Terminal Device for Estimating Battery Capacity,” which claims the benefit and priority of Hong Kong Patent Application No. 32020003991.7, filed on 10 Mar. 2020, the disclosures of which are incorporated herein by reference in their entireties.

### TECHNICAL FIELD

The present application relates to the technical field of battery management and in particular to a method, a device, a storage medium and a terminal for estimating the battery capacity.

### BACKGROUND

With the increasing spread of electric vehicles in the market, the demands on the battery performance of electric vehicles are getting higher and higher. As the service life of electric vehicles increases, the batteries that supply the power are getting older, so that the requirements of electric vehicles are no longer met by the battery power. In this case it is important to consider how to deal with the aging battery.

In fact, the power batteries retired from electric vehicles still have sufficient power for other applications, e.g., as large mobile power sources. In contrast to new batteries, however, the decommissioned power batteries still have the following deficiencies as mobile power sources:
1. The performance differences between discarded power batteries are great because the power batteries show different aging rates under different conditions of use. On the other hand, in use, the batteries are usually assembled to increase the voltage and capacity. The total capacity of a battery pack consisting of batteries with large differences in performance is reduced by some of the batteries with lower capacity and thus increases the risk of overcharging or over discharging during power generation.
2. An aged battery usually has a higher rate of aging than a new battery. Since the assessment of the battery charge depends on historical data, it is impossible to effectively assess the battery capacity of a battery that is aging too quickly.

### SUMMARY

The present application provides a method, a device, a storage medium and a terminal device for estimating the battery capacity in order to solve or alleviate one or more technical problems of the prior art.

As one aspect of the embodiments of the present application, an embodiment of the present application provides a method for estimating a battery capacity, comprising:
determining a measuring voltage of the battery before charging or discharging, an electric charge electric charge change of the battery during charging or discharging and a measuring voltage of the battery after charging or discharging;
obtaining correlation data between the voltage and electric charge of the battery;
updating the correlation data according to the measurement voltage of the battery before charging or discharging, the measurement voltage of the battery after charging or discharging, the electric charge change and the correlation data; and
determining the battery capacity according to the updated correlation data.

In one embodiment, the updating of the correlation data according to the measurement voltage of the battery before charging or discharging, the measurement voltage of the battery after charging or discharging, the electric charge change and the correlation data comprises the following steps:
obtaining an electric charge corresponding to a measurement voltage of the battery before charging or discharging from the correlation data as an estimated electric charge of the battery before charging or discharging;
summing the estimated electric charge before charging or discharging and the electric charge change to obtain an estimated electric charge of the battery after charging or discharging;
obtaining a voltage corresponding to the estimated electric charge of the battery after charging or discharging from the correlation data as an estimated voltage of the battery after charging or discharging;
determining a correction voltage of the battery after charging or discharging according to the estimated electric charge of the battery before charging or discharging, the electric charge change, the measurement voltage of the battery after charging or discharging and the estimated voltage of the battery after charging or discharging;
obtaining an estimated electric charge corresponding to the correction voltage obtained from the correlation data; and
updating the electric charge in the correlation data according to the estimated electric charge in the correlation data corresponding to the correction voltage, the electric charge change, and the estimated electric charge of the battery before charging or discharging.

In one embodiment, the method further comprises the following step:
updating the voltage in the correlation data corresponding to the estimated electric charge after charging or discharging according to the correction voltage of the battery after charging or discharging.

In one embodiment, the determining of a correction voltage of the battery after charging or discharging according to an estimated electric charge of the battery before charging or discharging, an estimated electric charge of the battery after charging or discharging, a measurement voltage of the battery after charging or discharging and an estimated voltage of the battery after charging or discharging comprises:

$${V}_{m} = \frac{{V}_{2} {Q}_{0} + {V}_{1} {C}_{n}}{{Q}_{0} + {C}_{n}}$$

where Vₘ indicates the correction voltage of the battery after charging or discharging, V₁ indicates the measurement voltage of the battery after charging or discharging, V₂ indicates the estimated voltage of the battery after charging or discharging, Q₀ indicates the estimated electric charge of the battery before charging or discharging, and Cₙ indicates the electric charge change.

In one embodiment, the updating of the electric charge in the correlation data according to the estimated electric charge corresponding to the correction voltage in the correlation data, the electric charge change and the estimated electric charge of the battery before charging or discharging comprises the following step:
for any electric charge that changes due to charging or discharging in the correlation data based on the estimated electric charge of the battery before charging or discharging, updating the charge according to the following formula:

$${Q}_{k}^{′} = {Q}_{0} + ( {Q}_{k} - {Q}_{0} ) \frac{{C}_{n}}{{Q}_{m} - {Q}_{0}}$$

where Qₖ′ indicates the charge after the update, Qₖ indicates the charge before the update, Q₀ indicates the estimated electric charge of the battery before charging or discharging, Qₘ indicates the estimated electric charge corresponding to the correction voltage in the correlation data, and Cₙ indicates the electric charge change.

In one embodiment, the determination of the battery capacity according to the updated correlation data comprises the following steps:
obtaining an upper limit voltage and a lower limit voltage;
obtaining a charge corresponding to the upper limit voltage and a charge corresponding to the lower limit voltage from the updated correlation data; and
determining the absolute value of the electric charge difference between the electric charge assigned to the upper limit voltage and the electric charge assigned to the lower limit voltage as the battery capacity.

In one embodiment, the determination of an electric charge change of the battery during charging or discharging comprises the following steps:
detecting an input current or output current of the battery according to a set frequency; and
multiplying each of the detected input currents or output currents by the reciprocal of the frequency and then summing to obtain the electric charge change of the battery during charging or discharging.

As one aspect of the exemplary embodiments of the present application, an exemplary embodiment of the present application provides an apparatus for estimating the battery capacity, which comprises:
a determination module for determining the measurement voltage of the battery before charging or discharging, an electric charge electric charge change of the battery during charging or discharging and the measurement voltage of the battery after charging or discharging;
an obtaining module for obtaining the correlation data between the voltage and electric charge of the battery;
an update module for updating the correlation data according to the measurement voltage of the battery before charging or discharging, the measurement voltage of the battery after charging or discharging, the electric charge change, and the correlation data; and
a battery capacity determination module for determining the battery capacity according to the updated correlation data.

In one embodiment, the update module comprises:
a first obtaining unit for obtaining an electric charge corresponding to the measured voltage of the battery before charging or discharging from the correlation data as an estimated electric charge of the battery before charging or discharging;
a summing unit for summing the estimated electric charge before charging or discharging and the electric charge change to obtain an estimated electric charge of the battery after charging or discharging;
a second obtaining unit for obtaining a voltage corresponding to the estimated electric charge of the battery after charging or discharging from the correlation data as the estimated voltage of the battery after charging or discharging;
a correction voltage determination unit for determining a correction voltage of the battery after charging or discharging according to the estimated electric charge of the battery before charging or discharging, the electric charge change, the measurement voltage of the battery after charging or discharging, and the estimated voltage of the battery after charging or discharging;
a third obtaining unit for obtaining an estimated electric charge corresponding to the correction voltage obtained from the correlation data; and
a charge update unit for updating the electric charge in the correlation data according to the estimated electric charge corresponding to the correction voltage in the correlation data, the electric charge change, and the estimated electric charge of the battery before charging or discharging.

As one aspect of the exemplary embodiments of the present application, an exemplary embodiment of the present application provides the following configuration that the structure for estimating a battery capacity comprises a processor and a memory, the memory being used for the determination device of the battery capacity to program the program that corresponds to the above estimation method of the battery capacity, and to execute the correlation data between the voltage and the charge of the battery, wherein the processor is configured to execute the program stored in the memory. The device for determining the battery capacity also comprises a communication interface via which the device for estimating the battery capacity can communicate with other devices or communication networks.

As one aspect of the embodiments of the present application, an embodiment of the present application provides a computer readable storage medium for computer software instructions. The computer software instructions are used by the battery capacity estimator and include a program for performing the battery capacity estimating method.

Using the above technical solution, the embodiment of the present application is able to accurately update the historical data of voltage and electric charge, and effectively evaluate the electric charge of the battery even if the battery ages too quickly.

The above description is for explanation only and does not mean any restrictions. In addition to the schematic aspects, embodiments and features described above, further aspects, embodiments and features of the present application can be readily understood by referring to the figures and the following detailed description.

### BRIEF DESCRIPTION OF THE DRAWINGS

In the drawings, unless otherwise specified, the same reference numerals refer to the same or similar parts or elements throughout the multiple drawings. The drawings are not necessarily drawn to scale. It should be understood that these drawings only depict some embodiments disclosed according to the present application, and should not be regarded as limiting the scope of the present application.

FIG. 1 shows a schematic flow diagram of a method for estimating the battery capacity, which is provided according to an exemplary embodiment of the present application.

FIG. 2 is a schematic flow diagram of an update process for correlation data which is provided according to an embodiment of the present application.

FIG. 3 is a graph of the variation in voltage with charge that is provided in accordance with an exemplary embodiment of the present application.

FIG. 4 is a schematic diagram of the structure of the battery capacity determining device provided according to an exemplary embodiment of the present application.

FIG. 5 shows a schematic diagram of the structure of the update module which is provided according to an exemplary embodiment of the present application.

FIG. 6 is a schematic diagram showing the structure of the terminal provided according to an embodiment of the present application.

### DETAILED DESCRIPTION OF EMBODIMENTS

Only certain exemplary embodiments are briefly described below. As can be recognized by a person skilled in the art, the exemplary embodiments described can be modified in the most varied of ways without departing from the scope or spirit of the application. Accordingly, the accompanying figures and description are to be regarded as exemplary rather than restrictive.

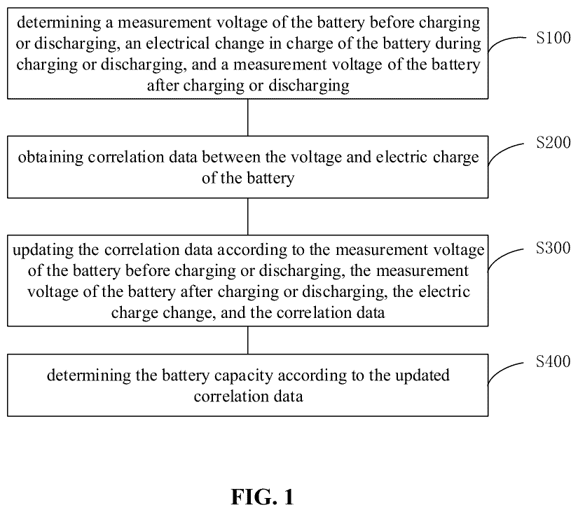

Referring to FIG. 1, FIG. 1 shows a flowchart of a method for estimating a battery capacity, which is provided according to an exemplary embodiment of the present application. As one aspect of the exemplary embodiment of the present application, an exemplary embodiment of the present application provides a method for estimating a battery capacity which can be carried out by a processor and which comprises steps S100 to S400 as follows:
S100, determining a measurement voltage of the battery before charging or discharging, an electric charge electric charge change of the battery during charging or discharging, and a measurement voltage of the battery after charging or discharging.

The battery can be placed in a mobile power supply or other type of power supply, and the battery can be either a new or an aged battery. When starting a power supply in a mobile power supply or when charging a power supply, the battery voltage is pre-measured, i.e., the measurement voltage of the battery before charging or discharging.

In some exemplary embodiments, the current when charging or discharging the battery is recorded in a short interval t, e.g., the current is recorded with a certain frequency-when charging or discharging. The electric charge flowing in or out of the battery can be calculated within a period of charging or discharging, e.g., n*tᵢ, i=1,2,3, . . . , n by Σᵢ₌₁ⁿIᵢtᵢ are calculated, where Iᵢ indicates the current detected in the i-th time period, which can be an instantaneous value or an average current value, tᵢ indicates the duration of the i-th time period. The individual time periods can be the same or different.
S200, obtaining correlation data between the voltage and electric charge of the battery.

Mobile power supply can include a variety of batteries. During assembly, each individual battery is tested so that a voltage-charge characteristic is obtained. This characteristic curve indicates that the electric charge varies with the voltage or the voltage varies with the charge. Therefore, such characteristics are used as correlation data for the batteries in this embodiment. In further exemplary embodiments, a set of points is used as correlation data instead of the characteristic curve, e.g., (VₓeQₓ), where Vₓ specifies the voltage of the xth point in the set of points and Qₓ specifies the electric charge of the xth point. In further embodiments, the variation in the battery voltage with the electric charge or the variation in the electric charge with the battery voltage can be represented by means of a one-to-one mapping function. The correlation data can be stored in the memory of the mobile power supply and read out by the processor.
S300, updating the correlation data according to the measurement voltage of the battery before charging or discharging, the measurement voltage of the battery after charging or discharging, the change in electric charge, and the correlation data.

In some embodiments, the voltage in the correlation data or the electric charge in the correlation data, even both the voltage and the electric charge in the correlation data, can be updated.
S400, determining the battery capacity according to the updated correlation data.

In this exemplary embodiment, the battery capacity is determined by the electric charge difference between the limit voltages. Therefore, the electric charge at the limit voltages is obtained from the updated correlation data. The actual battery capacity is determined according to the difference between the electric charge at the limit voltages.

In this exemplary embodiment, the correlation data are updated as a function of the measured change in voltage and the electric charge change of the battery before and after the charging or discharging of the correlation data and of the historically recorded correlation data. The actual battery capacity is then determined according to the updated correlation data.

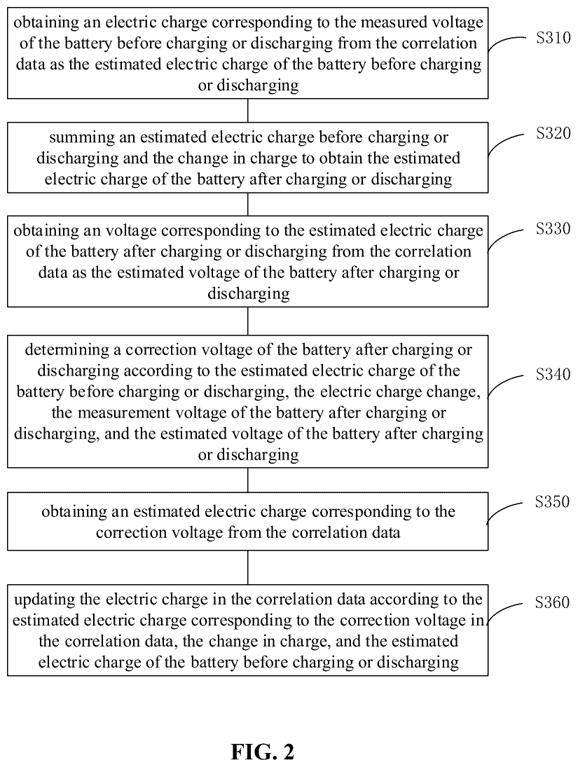

In some exemplary embodiments, as shown in FIG. 2, the aforementioned step S300 can comprise steps S310 to S360 as follows:
S310, obtaining an electric charge corresponding to the measured voltage of the battery before charging or discharging from the correlation data as the estimated electric charge of the battery before charging or discharging. For example, the measurement voltage of the battery before charging or discharging is 10 V. Then a data point with the voltage of 10 V is obtained from the correlation data. Therefore this data point is assumed to be (10 V, 100 Q). Here, 100 Q serves as the electric charge on the battery before charging or discharging. Since this electric charge is derived from the historical correlation data, it can be called an estimated electric charge.
S320, summing an estimated electric charge before charging or discharging and the electric charge change to obtain the estimated electric charge of the battery after charging or discharging. Assuming that the estimated electric charge of the battery before charging or discharging is 100 Q and the electric charge change is 200 Q, the estimated electric charge of the battery after charging or discharging is 300 Q.
S330, obtaining an voltage corresponding to the estimated electric charge of the battery after charging or discharging from the correlation data as the estimated voltage of the battery after charging or discharging. In the remainder of the previous example, it is assumed that the estimated electric charge after charging or discharging is 30002. Then, a data point with an estimated electric charge of 300 Q is obtained from the correlation data. Assuming this data point is (33 V, 300 Q), 33 V serves as the battery's estimate of voltage after charging or discharging. Since this voltage is derived from the historical correlation data, it can be referred to as an estimated voltage.
S340, determining a correction voltage of the battery after charging or discharging according to the estimated electric charge of the battery before charging or discharging, the electric charge change, the measurement voltage of the battery after charging or discharging, and the estimated voltage of the battery after charging or discharging. As explained above, since only the above-mentioned estimated voltage of the battery and the measurement voltage of the battery after charging or discharging can be obtained and they have errors, it is necessary in the present application to calculate a correction voltage of the battery after charging or discharging. On the one hand, this can be used for the updated correction of the corresponding voltage in the correlation data. On the other hand, this can be used to update the electric charge in the correlation data. The specific update process is related to the following two steps.

In some exemplary embodiments, the measured voltage of the battery after charging or discharging and the estimated voltage of the battery after charging or discharging are weighted by means of the estimated electric charge of the battery before charging or discharging and the electric charge change of the battery during charging or discharging to determine a correction voltage to maintain the battery after charging or discharging.
S350, obtaining an estimated electric charge corresponding to the correction voltage from the correlation data.
S360, updating the electric charge in the correlation data according to the estimated electric charge corresponding to the correction voltage in the correlation data, the electric charge change, and the estimated electric charge of the battery before charging or discharging.

In some embodiments, each individual charge in the correlation data since charging and discharging is updated by calculating the ratio between the electric charge change from the estimated electric charge, which corresponds to the corrective voltage of the battery after charging or discharging, to the estimated electric charge before charging or discharging and the actual electric charge change is used.

In some exemplary embodiments, the method based on step S340 further comprises the following step:
updating the voltage in the correlation data corresponding to the estimated electric charge after charging or discharging according to the correction voltage of the battery after charging or discharging.

It is assumed by way of example that the correction voltage of the battery after charging or discharging is 30 V and the estimated electric charge of the battery is 300 Q after charging or discharging. Then, a corresponding data point such as (33 V, 300 Q) is located in the correlation data according to the estimated electric charge of the battery 300 Q after charging or discharging, and then the 33 V in that data point is updated to 30 V.

In some embodiments, the formula for determining a correction voltage of the battery after charging or discharging according to an estimated electric charge of the battery before charging or discharging, an estimated electric charge of the battery after charging or discharging, a measurement voltage of the battery after charging or discharging, and an estimated voltage of the battery after charging or discharging is:

$${V}_{m} = \frac{{V}_{2} {Q}_{0} + {V}_{1} {C}_{n}}{{Q}_{0} + {C}_{n}}$$

where Vₘ indicates the correction voltage of the battery after charging or discharging, V₁ indicates the measurement voltage of the battery after charging or discharging, V₂ indicates the estimated voltage of the battery after charging or discharging, Q, indicates the estimated electric charge of the battery before charging or discharging, and Cₙ indicates the electric charge change.

For example, if Q₀ is 100 Q, Cₙ is 200 Q, V₁ is 30V and V₂ is 33 V, then the correction voltage of the battery after charging or discharging is:

$${V}_{m} = \frac{33 V * 100 Q + 30 V * 200 Q}{100 Q + 200 Q} = 31 V$$

In this exemplary embodiment, the measurement voltage of the battery after charging or discharging has a greater weight if the electric charge change during charging or discharging is too great. On the other hand, the estimated voltage of the battery after charging or discharging is heavier when the original electric charge during charging or discharging is large, that is, when the estimated electric charge before charging or discharging has a larger value. Therefore, the estimated and measured voltages of the batteries after charging or discharging are weighted averaged according to the electric charge before charging or discharging and the electric charge change during charging or discharging, so that a corrected voltage after charging or discharging is obtained.

In some exemplary embodiments, in step S360 above, the charge can be updated in accordance with the following formula in the correlation data for any electric charge that changes due to the charging or discharging, based on the estimated electric charge of the battery before charging or discharging.

$${Q}_{k}^{′} = {Q}_{0} + ( {Q}_{k} - {Q}_{0} ) \frac{{C}_{n}}{{Q}_{m} - {Q}_{0}}$$

where Qₖ indicates the charge after the update, Qₖ indicates the charge before the update, Q₀ indicates the estimated electric charge of the battery before charging or discharging, Qₘ indicates the estimated electric charge corresponding to the correction voltage in the correlation data, and Cₙ indicates the electric charge change.

With the change in electric charge is Cₙ and the voltage drops to Vₘ, the charge stored in the memory is changed in this embodiment, i.e., the electric charge change Qₘ−Q₀, which varies with the voltage, is recorded in the correlation data. Then there is the ratio of the actual electric charge change to the electric charge change stored in the memory,

$$\frac{{C}_{n}}{{Q}_{m} - {Q}_{0}} .$$

At the same time, the actual electric charge change of the data point corresponding to Qₖ in the correlation data with respect to the data point of Q₀ is also proportional to (Qₖ−Q₀).

In some embodiments, upper step S400 may include the following steps.

First, an upper limit voltage and a lower limit voltage are obtained. regarding the upper limit voltage and the lower limit voltage, they can be adapted from the historical correlation data or reset if necessary.

Then, the electric charge corresponding to the upper limit voltage and the electric charge corresponding to the lower limit voltage are obtained from the updated correlation data.

Finally, the absolute value of the electric charge difference between the electric charge assigned to the upper limit voltage and the electric charge assigned to the lower limit voltage is determined as the battery capacity.

In the battery management system of the mobile power supply, an upper and a lower limit voltage are usually preset, each representing the maximum and minimum battery voltage. Therefore, the battery capacity is between the charge corresponding to the highest voltage and the charge corresponding to the lowest voltage. After the charging/discharging characteristic has been corrected, the battery capacity is calculated again.

In some exemplary embodiments, the method for determining the electric charge change of the battery during charging or discharging in the above step S100 can comprise the following steps: detecting an input current or an output current of the battery according to a set frequency; multiplying each of the sensed input currents or output currents by the reciprocal of the frequency and then summing to get the electric charge change of the battery during charging or discharging. The frequency on which the sampling or detection is based can be fixed or, if necessary, adjustable. This frequency is adjusted e.g., according to the variation of the sampled current in the past.

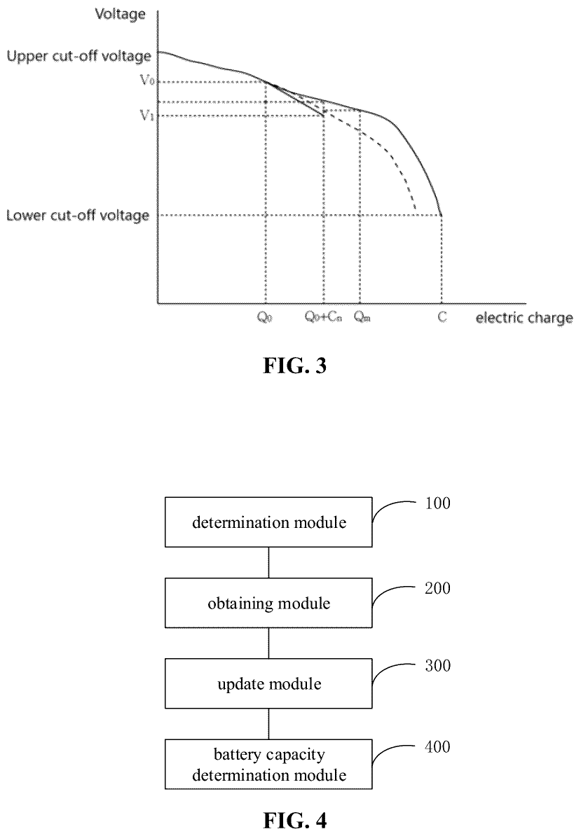

As an exemplary embodiment, see FIG. 3, an embodiment of the present invention provides a battery management system that can evaluate the electric charge of the battery in real time. The battery management system includes a processor, a voltmeter, an ammeter and a memory. Each time the battery is assembled, the battery is tested in order to obtain a voltage-charge characteristic. On the basis of the characteristic curve obtained, the upper and lower limit voltages are determined and the battery capacity is calculated. The voltage-charge characteristic, the upper limit voltage, the lower limit voltage and the battery capacity are stored in the memory of the battery management system.

When the power supply is switched on, the operating voltage of the battery V₀ is measured and the electric charge Q₀ corresponding to this operating voltage V₀ is found from the voltage-charge characteristic.

When charging or discharging, the input or output current of the battery is measured in a very short period of time t, and the electric charge change for a certain period of time (n*tᵢ) can be calculated as d.h. Cₙ=Σᵢ₌₁ⁿIᵢtᵢ.

After charging or discharging, the voltage of the battery V₁ is measured again.

The voltage V₂, which corresponds to the battery charge (Q₀+Cₙ) after charging or discharging, is obtained from the correlation data of the voltage change with the charge stored in the memory. This can be determined by reading out the data stored in the memory. Each record in the correlation data can be represented as (Vₓ, Qₓ). Reading out the memory shows that V₂ is the corresponding voltage in the correlation data for the electric charge Q₀+Cₙ.

When Q₀+Cₙ is charged, the voltage stored in the memory is corrected as follows:

$${V}_{m} = \frac{{V}_{2} {Q}_{0} + {V}_{1} {C}_{n}}{{Q}_{0} + {C}_{n}}$$

This formula corrects the voltage according to both the voltage data actually recognized and the historical voltage data stored in the memory.

If the electric charge change of the battery during charging or discharging is large (Cₙ), the weight of the measured voltage of the battery V₁ after charging or discharging is relatively large. If the original electric charge of the battery is large, i.e., the electric charge of the battery before charging or discharging is large, the weight of the voltage of the battery V₂ recorded in the historical correlation data is greater after charging or discharging. Thus, the above formula is available for correcting the voltage.

In the memory, the charge Qₖ corresponds to the voltage Vₖ. (Vₖ, Qₖ) is located in the characteristic curve behind the point (V₂, Q₀). According to the corrected voltage Vₘ, a corresponding charge Qₘ is determined in the data stored in the original memory. Using the Qₘ the electric charge Qₖ stored in the memory, which corresponds to the voltage Vₖ, is corrected as follows:

$${Q}_{k}^{′} = {Q}_{0} + ( {Q}_{k} - {Q}_{0} ) \frac{{C}_{n}}{{Q}_{m} - {Q}_{0}}$$

The corrected electric charge Qₖ is stored in the memory of the system.

When the change in electric charge is Cₙ, and the voltage drops to Vₘ, the change stored in the original memory becomes Qₘ−Q₀. Then the ratio of the actual change in electric charge and the charge stored in the memory is

$$\frac{{C}_{n}}{{Q}_{m} - {Q}_{0}} .$$

For any Qₖ, the difference between the charge corresponding to Qₖ and charge Q is proportional to the difference between the charge Qₖ and charge Q₀ recorded in the memory and their ratio is

$$\frac{{C}_{n}}{{Q}_{m} - {Q}_{0}} .$$

On the basis of the updated voltage/charge data and the set limit voltage, the battery capacity Q is in turn calculated and the capacity stored in the memory is updated.

An upper and a lower limit voltage are usually provided within the battery management system, each representing the maximum and minimum battery voltage. Therefore, the battery capacity is defined as a change from the charge corresponding to the highest voltage to the charge corresponding to the lowest voltage. After the discharge characteristic has been corrected, the battery capacity is calculated again.

As one aspect of the exemplary embodiments of the present application, see FIG. 4, an exemplary embodiment of the present application provides an apparatus for determining a battery capacity, comprising:
a determination module 100 for determining a measurement voltage of the battery before charging or discharging, an electric charge change of the battery during charging or discharging and a measurement voltage of the battery after charging or discharging;
an obtaining module 200 for obtaining the correlation data between the voltage and electric charge of the battery;
an update module 300 for updating the correlation data according to the measurement voltage of the battery before charging or discharging, the measurement voltage of the battery after charging or discharging, the electric charge change, and the correlation data; and
a battery capacity determination module 400 for determining the battery capacity according to the updated correlation data.

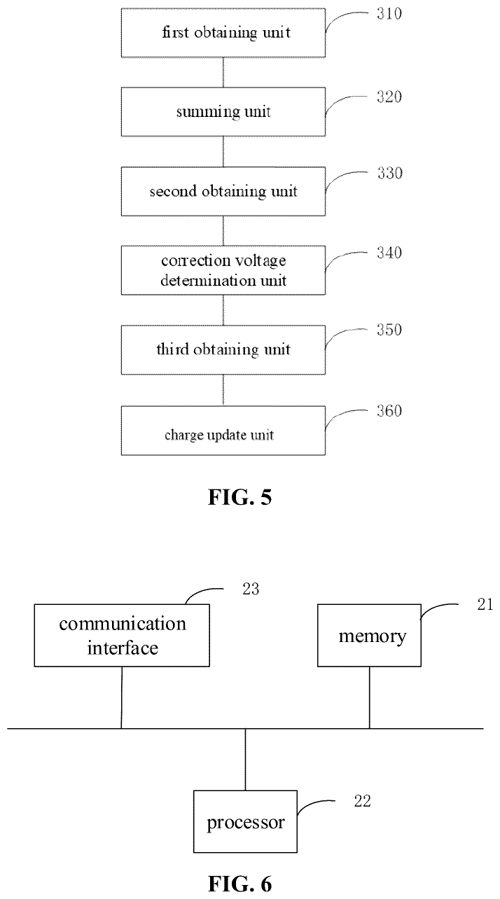

In one embodiment, see FIG. 5, the update module 300 comprises:
a first obtaining unit 310 for obtaining an electric charge corresponding to the measurement voltage of the battery before charging or discharging from the correlation data as an estimated electric charge of the battery before charging or discharging;
a summing unit 320 for summing the estimated electric charge before charging or discharging and the electric charge change to obtain the estimated electric charge of the battery after charging or discharging;
a second obtaining unit 330 for obtaining the voltage corresponding to the estimated electric charge of the battery after charging or discharging from the correlation data as the estimated voltage of the battery after charging or discharging;
a correction voltage determination unit 340 for determining a correction voltage of the battery after charging or discharging according to the estimated electric charge of the battery before charging or discharging, the electric charge change, the measurement voltage of the battery after charging or discharging, and the estimated voltage of the battery after charging or discharging;
a third obtaining unit 350 for obtaining the estimated electric charge corresponding to the correction voltage from the correlation data; and
a charge update unit 360 for updating the electric charge in the correlation data according to the estimated electric charge corresponding to the correction voltage in the correlation data, the electric charge change, and the estimated electric charge of the battery before charging or discharging.

In some exemplary embodiments, the update module 300 further comprises:
a voltage update unit for updating the voltage in the correlation data, which corresponds to the estimated electric charge after charging or discharging, according to the correction voltage of the battery after charging or discharging.

In some embodiments, the correction voltage determination unit 340 includes the following formula:

$${V}_{m} = \frac{{V}_{2} {Q}_{0} + {V}_{1} {C}_{n}}{{Q}_{0} + {C}_{n}}$$

where Vₘ indicates the correction voltage of the battery after charging or discharging, V₁ indicates the measurement voltage of the battery after charging or discharging, V₂ indicates the estimated voltage of the battery after charging or discharging, Q₀ indicates the estimated electric charge of the battery before charging or discharging, and Cₙ indicates the electric charge change.

In some exemplary embodiments, the charge update unit 360 is used to ensure that for any electric charge that changes due to charging or discharging, the correlation data is updated based on the estimated electric charge of the battery before charging or discharging according to the following formula:

$${Q}_{k}^{′} = {Q}_{0} + ( {Q}_{k} - {Q}_{0} ) \frac{{C}_{n}}{{Q}_{m} - {Q}_{0}}$$

where Qₖ′ indicates the charge after the update, Qₖ indicates the charge before the update, Q₀ indicates the estimated electric charge of the battery before charging or discharging, Qₘ indicates the estimated electric charge corresponding to the correction voltage in the correlation data, and Cₙ indicates the electric charge change.

In some exemplary embodiments, the battery capacity determination module 400 comprises:
a limit voltage obtaining unit for obtaining an upper limit voltage and a lower limit voltage;
an electric charge holding unit for obtaining a charge corresponding to the upper limit voltage and a charge corresponding to the lower limit voltage from the updated correlation data; and
a capacity calculation unit for determining the absolute value of the electric charge difference between the electric charge assigned to the upper limit voltage and the electric charge assigned to the lower limit voltage as battery capacity.

In some exemplary embodiments, the determination module 100 comprises:
a detection unit for detecting the input current or the output current of the battery according to a set frequency; and
a charge change determining unit for multiplying each detected input current or output current by the reciprocal of the frequency and then summing to obtain the electric charge change of the battery during charging or discharging.

The functions of the device can be implemented by hardware or by appropriate software executed by hardware. The hardware or software comprises one or more modules corresponding to the functions mentioned above.

As an example of the exemplary embodiments of the present application, an exemplary embodiment of the present application provides the following configuration that the structure for estimating a battery capacity comprises a processor and a memory, the memory being used for the estimating device of the battery capacity to execute the program that corresponds to the above estimation method of the battery capacity, and to execute the correlation data between the voltage and the charge of the battery, the processor being configured to execute the program stored in the memory. The estimation device for the battery capacity also comprises a communication interface via which the estimation device for the battery capacity can communicate with other devices or communication networks.

The device further comprises:
a communication interface 23 for communication between a processor 22 and external devices; and
a memory 21 which may comprise high speed RAM memory as well as non-volatile memory such as at least one disk memory.

If the memory 21, the processor 22 and the communication interface 23 are implemented independently of one another, the memory 21, the processor 22 and the communication interface 23 can be connected to one another via a bus and thus communication takes place with one another. The bus can be an ISA (Industry Standard Architecture) bus, a PCI (External Device Interconnect) bus, or an EISA (Extended Industry Standard Architecture) bus, and so on. The buses can be classified as an address bus, data bus, control bus, etc. To simplify the illustration, only a thick line is shown in FIG. 6, but this does not mean that there is only one bus or one bus type.

Optionally, the memory 21, the processor 22 and the communication interface 23 can be integrated on a single chip in a specific embodiment. The memory 21, the processor 22 and the communication interface 23 can then communicate with one another via an internal interface.

In the description of this invention, the terms “an embodiment”, “some embodiments”, “example”, “specific examples” or “some examples” mean the specific features, structures, materials or properties used in connection with the embodiment or the examples are included in at least one embodiment or an example of the application. In addition, the specific features, structures, materials or properties described can be combined in a suitable manner in one or more exemplary embodiments or examples. In addition, the person skilled in the art can combine the various exemplary embodiments or examples described therein, as well as the features of the various exemplary embodiments or examples, without contradicting one another.

Furthermore, the terms “first” and “second” are used for descriptive purposes only and are not to be construed as explicitly or implying relative relevance or implying the number of technical features specified. A feature delimited by “first” and “second” can expressly or implicitly include at least one such feature. In the description of the present application, “plural” means two or more, unless expressly and specifically restricted otherwise.

Any process or method description described in the flowchart or otherwise described herein can be understood to represent a module, excerpt, or part of code that includes one or more executable instructions for implementing the steps of a particular logical function or process, and the preferred embodiments of the present application encompass additional implementations in which the functions cannot be performed in the order shown or spoken, including in basically the same manner or in reverse order depending on the functions, this to one skilled in the art Field to which the embodiments of the present application pertain should be understood.

For example, the logic and/or steps depicted in the flowchart or otherwise described herein may be viewed as a definitive list of executable instructions for implementing a logical function specifically implemented in any computer readable medium for use by an instruction execution system, apparatus, or device may (e.g., a computer-based system, a system with a processor, or any other system that can accept and execute the instructions from an instruction execution system, device, or device) or in combination with such instruction execution system, device, or device. For purposes of describing the application, a “computer readable medium” can be any device that can contain, store, communicate, distribute, or transmit a program for use by or in connection with an instruction execution system, device, or device.

The computer readable medium of the embodiments of the present application can be a computer readable signal medium or a computer readable storage medium, or any combination of the two. More specific examples of computer readable storage media include at least (non-exhaustive list) the following devices: electrical connector (electronic device) with one or more wirings, portable computer disk cartridge (magnetic device), random access memory (RAM), read only memory (ROM), erasable, editable Read-only memory (EPROM or flash memory), fiber optic device and a portable read-only memory (CDROM). Alternatively, the computer-readable storage medium can also be paper or another suitable medium on which a program can be printed, since the program can be obtained electronically, e.g., by optical scanning of the paper or another medium, followed by processing, decoding or, if necessary, other appropriate processing, and then stored in computer memory.

In the exemplary embodiments of the present application, the computer-readable signal medium can comprise a data signal which is propagated in baseband or as part of a carrier wave and which carries computer-readable program code. Such propagated data signals can take a variety of forms including, but not limited to, electromagnetic signals, optical signals, or any suitable combination of the foregoing. The computer-readable signaling medium can also be any computer-readable medium other than a computer-readable storage medium. The computer readable medium sends, propagates, or transmits a program for use by or in connection with an instruction execution system, input method, or apparatus. The program code contained on the computer readable medium can be transmitted over any suitable medium including, but not limited to: wireless, cable, fiber optic cable, radio frequency (RF), or the like, or any suitable combination of the foregoing.

It should be understood that the various parts of the present application can be implemented with hardware, software, firmware, or a combination thereof. In the above embodiments, multiple steps or methods can be implemented with software or firmware stored in memory and executed by a suitable instruction execution system. For an implementation with hardware, as in another implementation, any of the following prior art techniques or their combination can be used: discrete logic circuits with logic gate circuits for implementing logic functions on data signals, dedicated integrated circuits with suitable combinations of logic gate circuits, programmable gate arrays (PGAs), field-programmable gate arrays (FPGAs) or similar.

A person skilled in the art can understand that all or some of the steps with which the method of the embodiments described above is implemented can be performed by programs for instructing the associated hardware, and that the program can be stored in a computer-readable storage medium when performing the Program will contain one of the steps of the exemplary embodiment of the method or a combination thereof.

In addition, individual functional units in various exemplary embodiments of the present application can be integrated into a processing module, or they can be physically separate, or two or more units can be integrated into a single module. The above-mentioned integrated modules can be implemented either in hardware or in software function modules. The integrated module can also be stored in a computer-readable storage medium if it is implemented as a software functional module and sold or used as a stand-alone product. The storage medium can be a read-only memory, a floppy disk or a CD-ROM, and so on.

The above describes only the specific embodiment of this application, the scope of protection of the application is not limited thereby, and other variations can be derived therefrom by those skilled in the art without departing from the scope of the invention. The scope of protection of this application is therefore based on the scope of protection of the claims.

What is claimed is:

1. A method for estimating a battery capacity, comprising:
determining a measuring voltage of a battery before charging or discharging, an electric charge change of the battery during charging or discharging, and a measuring voltage of the battery after charging or discharging;
obtaining correlation data between a battery voltage and a battery electric charge;
updating the correlation data according to the measurement voltage of the battery before charging or discharging, the measurement voltage of the battery after charging or discharging, the electric charge change, and the correlation data; and
determining the battery capacity according to the updated correlation data;
wherein the step of the updating of the correlation data comprises:
obtaining an electric charge corresponding to a measurement voltage of the battery before charging or discharging from the correlation data as an estimated electric charge of the battery before charging or discharging;
summing the estimated electric charge before charging or discharging and the electric charge change to obtain an estimated electric charge of the battery after charging or discharging;
obtaining a voltage corresponding to the estimated electric charge of the battery after charging or discharging from the correlation data as an estimated voltage of the battery after charging or discharging;
determining a correction voltage of the battery after charging or discharging according to the estimated electric charge of the battery before charging or discharging, the electric charge change, the measurement voltage of the battery after charging or discharging, and the estimated voltage of the battery after charging or discharging;
using the correlation data to find an estimated electric charge corresponding to the value of-the correlation data; and
updating an electric charge in the correlation data according to the estimated electric charge in the correlation data corresponding to the correction voltage, the electric charge change, and the estimated electric charge of the battery before charging or discharging;
wherein the step of updating of the electric charge in the correlation data comprises:
for any electric charge that changes due to charging or discharging in the correlation data based on the estimated electric charge of the battery before charging or discharging, updating the electric charge according to the following formula:
$${Q}_{k}^{′} = {Q}_{0} + ( {Q}_{k} - {Q}_{0} ) \frac{{C}_{n}}{{Q}_{m} - {Q}_{0}}$$
where Qₖ′ indicates the charge after the update, Qₖ indicates the charge before the update, Q₀ indicates the estimated electric charge of the battery before charging or discharging, Qₘ indicates the estimated electric charge corresponding to the correction voltage in the correlation data, and Cₙ indicates the electric charge change.

2. The method according to claim 1, comprising:
updating a voltage in the correlation data corresponding to the estimated electric charge after charging or discharging according to the correction voltage of the battery after charging or discharging.

3. The method according to claim 1, wherein the determination of a correction voltage of the battery after charging or discharging comprises:
$${V}_{m} = \frac{{V}_{2} {Q}_{0} + {V}_{1} {C}_{n}}{{Q}_{0} + {C}_{n}}$$
where Vₘ indicates the correction voltage of the battery after charging or discharging, V₁ indicates the measurement voltage of the battery after charging or discharging, V₂ indicates the estimated voltage of the battery after charging or discharging, Q₀ indicates the estimated electric charge of the battery before charging or discharging, and Cₙ indicates the electric charge change.

4. The method according to claim 1, wherein the step of determining of the battery capacity according to the updated correlation data comprises:
obtaining an upper limit voltage and a lower limit voltage;
obtaining a charge corresponding to the upper limit voltage and a charge corresponding to the lower limit voltage from the updated correlation data; and
determining an absolute value of an electric charge difference between an electric charge assigned to the upper limit voltage and an electric charge assigned to the lower limit voltage as the battery capacity.

5. The method according to claim 1, wherein the step of determining an electric charge change of the battery during charging or discharging comprises:
detecting an input current or output current of the battery according to a set frequency; and
multiplying the detected input currents or output currents by the reciprocal of the frequency and then summing to obtain the electric charge change of the battery during charging or discharging.

6. An apparatus for estimating a battery capacity, comprising:
a determination module for determining a measuring voltage of the battery before charging or discharging, an electric charge change of the battery during charging or discharging and a measuring voltage of the battery after charging or discharging;
an obtaining module for obtaining correlation data between a battery voltage and a battery electric charge;
an update module for updating the correlation data according to the measurement voltage of the battery before charging or discharging, the measurement voltage of the battery after charging or discharging, the electric charge change, and the correlation data; and
a battery capacity determination module for determining the battery capacity according to the updated correlation data.

7. The apparatus according to claim 6, wherein the update module comprises:
a first obtaining unit for obtaining an electric charge corresponding to the measurement voltage of the battery before charging or discharging from the correlation data as an estimated electric charge of the battery before charging or discharging;
a summing unit for summing the estimated electric charge of the battery before charging or discharging and the electric charge change to obtain an estimated electric charge of the battery after charging or discharging;
a second obtaining unit for obtaining a voltage corresponding to the estimated electric charge of the battery after charging or discharging from the correlation data as the estimated voltage of the battery after charging or discharging;
a correction voltage determination unit for determining a correction voltage of the battery after charging or discharging according to the estimated electric charge of the battery before charging or discharging, the electric charge change, the measurement voltage of the battery after charging or discharging, and the estimated voltage of the battery after charging or discharging;
a third obtaining unit for obtaining an estimated electric charge by using the correlation data to find an estimated electric charge corresponding to the value of correction voltage; and
a charge update unit for updating the electric charge in the correlation data according to the estimated electric charge found by using the correlation data to find the estimate electric charge which corresponds to the correction voltage.

8. A terminal device, which comprises:
one or more processors;
a storage device for storing one or more programs;
wherein the one or more programs are executed by the one or more processors, and the one or more processors carry out a method according to claim 1.
